(19) United States
(12) Patent Application Publication
(10) Pub. No.: US 2024/0339336 A1
(43) Pub. Date: Oct. 10, 2024

(54) SUBSTRATE HAVING UNDERFILL DAM AND SEMICONDUCTOR PACKAGE INCLUDING THE SAME, AND METHOD FOR MANUFACTURING THE SEMICONDUCTOR PACKAGE

(71) Applicant: Samsung Electronics Co., Ltd., Suwon-si (KR)

(72) Inventor: Eunsu Lee, Suwon-si (KR)

(21) Appl. No.: 18/538,631

(22) Filed: Dec. 13, 2023

(30) Foreign Application Priority Data
Apr. 7, 2023 (KR) 10-2023-0046077

(51) Int. Cl. H01L 21/56; H01L 23/00; H01L 23/31; H01L 23/498; H01L 23/538; H01L 25/00; H01L 25/065

(52) U.S. Cl. CPC H01L 21/563; H01L 23/3128; H01L 23/49816; H01L 23/5386; H01L 24/16; H01L 24/32; H01L 24/48; H01L 24/73; H01L 24/81; H01L 24/83; H01L 24/85; H01L 24/92; H01L 25/0657; H01L 25/50; H01L 2224/16227; H01L 2224/26175; H01L 2224/32145; H01L 2224/32225; H01L 2224/48227; H01L 2224/73204; H01L 2224/73265; H01L 2224/81; H01L 2224/83007; H01L 2224/85; H01L 2224/92125; H01L 2225/06568

(57) ABSTRACT

A semiconductor package includes: a substrate including a first surface and a second surface opposite the first surface, a bottom die electrically connected to first bonding pads on the first surface of the substrate; a top die on the bottom die and electrically connected to second bonding pads on the first surface of the substrate by wires, an underfill in a gap between the substrate and the bottom die, an underfill dam surrounding the first bonding pads and the second bonding pads on the first surface of the substrate and is configured to restrict diffusion of the underfill, a mold that at least partially covers elements on the first surface of the substrate, and a plurality of solder balls on the second surface of the substrate. The second bond pads and a part of each of the wires bonded to the second bonding pads are immersed in the underfill.

### CROSS-REFERENCE TO RELATED APPLICATION

This application claims priority to and the benefit of Korean Patent Application No. 10-2023-0046077, filed in the Korean Intellectual Property Office on Apr. 7, 2023, the entire contents of which are incorporated herein by reference.

### BACKGROUND

The present disclosure relates to a substrate provided with a dam on its surface to limit diffusion of an underfill solution, a semiconductor package including the substrate, and a manufacturing method of the semiconductor package. The semiconductor package may include a bottom die flip-chip bonded to the substrate and a top die wire-bonded to the substrate.

Packaging, as a post-process of semiconductor manufacturing, has been highly evaluated recently. Various types of packaging technologies have been proposed, and some semiconductor packages may include a plurality of semiconductor dies.

When a semiconductor package includes a plurality of semiconductor dies, two or more semiconductor dies are mounted on a carrier such as a substrate. For high integration, two or more semiconductor dies may be stacked in vertical direction. Among the vertically stacked semiconductor dies, a bottom die may be directly electrically connected by solder bumps on the substrate. On the other hand, various methods are used to electrically connect a top die stacked on the bottom die to the substrate.

One way to electrically connect the top die to the substrate is wire bonding. The bottom die is electrically connected to the bonding pads on the first surface of the substrate by flip-chip bonding, and the top die is electrically connected to the bonding pads on the first surface of the substrate by wire bonding.

Meanwhile, a gap between the bottom die and the first surface of the substrate is filled by an underfill. The underfill not only secures electrical insulation between bumps, but also contributes to adhesion between the bottom die and the substrate.

In an underfill process, an underfill solution is applied from one side of the bottom die to flow into a gap between the bottom die and the first surface of the substrate. The underfill solution spreads readily outward simultaneously as it flows into the gap between the bottom die and the first surface of the substrate. After providing an appropriate amount of underfill solution, the underfill solution is cured at an appropriate temperature. In this case, the underfill solution may generate fume. The underfill fume may contaminate the surface of the bonding pad where the wire is not yet bonded, which may lead to bonding failure. It is assumed that the underfill fume forms a film on the surface of the bonding pad.

### SUMMARY

Embodiments of the present disclosure provide a way for preventing a bonding defect from occurring when a wire is bonded to a bonding pad by preventing contamination of the bonding pad due to underfill fume.

According to a first aspect of the present disclosure, a substrate for a semiconductor package is provided. The substrate for a semiconductor package includes: a first surface configured to receive a semiconductor chip; a second surface opposite the first surface; a plurality of bonding pads on the first surface; and an underfill dam surrounding the plurality of bonding pads and configured to limit diffusion of an underfill, wherein the plurality of bonding pads include first bonding pads for flip-chip bonding and second bonding pads disposed around the first bonding pads for wire bonding.

In some embodiments, the underfill dam may be an insulation layer with a thickness of 10 μm or more.

In some embodiments, the insulation layer may be a solder resist (SR) coated on the first surface.

In some embodiments, the substrate for the semiconductor package may further include third bonding pads for wire bonding on the underfill dam.

In some embodiments, the substrate for the semiconductor package may further include third bonding pads for wire bonding outside the underfill dam on the first surface.

According to a second aspect of the present disclosure, a semiconductor package is provided. The semiconductor package includes: a substrate including a first surface and a second surface opposite the first surface; a bottom die electrically connected to first bonding pads on the first surface of the substrate by solder bumps; a top die on the bottom die and electrically connected to second bonding pads on the first surface of the substrate by wires; an underfill in a gap between the substrate and the bottom die; an underfill dam surrounding the first bonding pads and the second bonding pads on the first surface of the substrate and is configured to restrict diffusion of the underfill; a mold that at least partially covers elements on the first surface of the substrate; and a plurality of solder balls on the second surface of the substrate, wherein the second bonding pads and a part of each of the wires bonded to the second bonding pads are immersed in the underfill.

In some embodiments, the underfill dam may have a thickness of 10 μm or more and has a maximum height lower than a maximum height of the bottom die.

In some embodiments, the underfill dam may be a solder resist (SR) coated on the first surface of the substrate.

In some embodiments, the second bonding pads may extend along at least one side of the bottom die and may not extend along at least one other side of the bottom die.

In some embodiments, the second bonding pads may be adjacent three sides of the bottom die, and a region for implantation of an underfill solution may be provided on the remaining one side of the bottom die.

In some embodiments, the semiconductor package may further include third bonding pads for wire bonding on the underfill dam.

In some embodiments, the third bonding pad may be electrically connected to the top die by wires.

In some embodiments, the semiconductor package may further include an additional chip on the top die, wherein the third bonding pad is electrically connected to the additional chip by wires.

In some embodiments, the semiconductor package may further include third bonding pads for wire bonding outside the underfill dam on the first surface of the substrate.

In some embodiments, the third bonding pad may be electrically connected to the top die by wires.

In some embodiments, the semiconductor package may further include an additional chip on the top die, wherein the third bonding pads are electrically connected to the additional chip by wires.

In some embodiments, the semiconductor package may further include an additional chip on the top die, wherein a portion of the second bonding pads are electrically connected to the top die, and another portion of the second bonding pads are electrically connected to the additional chip.

In some embodiments, the top die includes a plurality of top dies, and each of the top dies is electrically connected to adjacent ones of the second bonding pads by wires.

According to a third aspect of the present disclosure, a manufacturing method of a semiconductor package is provided. The manufacturing method includes: preparing a substrate including a plurality of bonding pads and an underfill dam surrounding the plurality of bonding pads on a first surface of the substrate; mounting a bottom die on the first surface of the substrate, wherein the bottom die is electrically connected to first bonding pads among the plurality of bonding pads by flip-chip bonding; attaching a top die to an upper surface of the bottom die; electrically connecting the top die to second bonding pads among the plurality of bonding pads by wire bonding; providing an underfill solution into a region surrounded by the underfill dam until a gap between the bottom die and the first surface of the substrate is filled by the underfill solution and the second bonding pads and a part of each of the wires bonded to the second bonding pads are immersed in the underfill solution; curing the underfill solution; molding the first surface of the substrate; and providing a plurality of solder bumps on a second surface of the substrate opposite the first surface of the substrate.

In some embodiments, the preparing the substrate may include preparing the underfill dam by coating a solder resist (SR) on a region surrounding the plurality of bonding pads on the first surface of the substrate.

According to embodiments of the present disclosure, the underfill dam surrounds the bonding pads and thus it is possible to limit the diffusion or unwanted spreading of the underfill solution.

In addition, the bonding pads for wire bonding are disposed inside the underfill dam and the wire bonding is performed before the underfill process such that the underfill covers the bonding pads to which wires are bonded thereby reliably preventing contamination of the bonding pad due to underfill fume and strengthening bonding between the bonding pad and the wire.

In addition, since the bonding pad for wire bonding is covered by the underfill, there is no need to dispose the bonding pads for wire bonding at a distance greater than a certain distance from the bonding pads for flip-chip bonding, thereby achieving down-size semiconductor packages.

In addition, since the bonding pads are disposed with a high density, the occurrence of warpage can be suppressed.

### BRIEF DESCRIPTION OF THE DRAWINGS

FIG. 1 is a schematic top plan view of a substrate for a semiconductor package according to embodiments of the present disclosure.

FIG. 2 is a schematic cross-sectional view of the substrate for the semiconductor package of FIG. 1.

FIG. 3 is a schematic top plan view of a semiconductor package according to embodiments of the present disclosure.

FIG. 4 is a schematic cross-sectional view of the semiconductor package of FIG. 3.

FIG. 5 is a schematic cross-sectional view of a semiconductor package according to other embodiments of the present disclosure.

FIG. 6 is a schematic top plan view of a semiconductor package according to other embodiments of the present disclosure.

FIG. 7 is a cross-sectional view of the semiconductor package of FIG. 6.

FIG. 8 is a schematic top plan view of a semiconductor package according to other embodiments of the present disclosure.

FIG. 9 is a schematic cross-sectional view of the semiconductor package of FIG. 8.

FIG. 10 is a schematic top plan view of a semiconductor package according to other embodiments of the present disclosure.

FIG. 11 is a schematic cross-sectional view of the semiconductor package of FIG. 10.

FIG. 12 is a schematic top plan view of a semiconductor package according to other embodiments of the present disclosure.

FIG. 13 is a schematic cross-sectional view of the semiconductor package of FIG. 12.

FIG. 14 to FIG. 20 are provided for description of a manufacturing method of a semiconductor package according to embodiments of the present disclosure.

### DETAILED DESCRIPTION

Hereinafter, with reference to accompanying drawings, various embodiments of the present disclosure will be described in detail and thus a person of an ordinary skill can readily practice them in the technical field to which the present disclosure belongs. The present disclosure may be implemented in many different forms and is not limited to the embodiments described herein.

In order to clearly explain the present disclosure, parts irrelevant to the description may be omitted, and the same reference numerals are used for the same or similar constituent elements throughout the specification.

In addition, the size and thickness of each component shown in the drawing may be arbitrarily represented for the convenience of description, and thus the present disclosure is not necessarily limited to the drawings. In the drawings, the thickness of layers, films, panels, regions, etc., may be exaggerated for clarity. In addition, in the drawings, for convenience of explanation, the thickness of some layers and regions may be exaggerated.

In addition, in the drawings, bumps, metal pads, and vias may be enlarged and exaggerated compared to other elements to better show the structure.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to mean positioned above or below or on the side of the target element, and will not necessarily be understood to mean positioned “at an upper side” based on an opposite to gravity direction.

In addition, unless explicitly described to the contrary, the word “comprise”, and variations such as “comprises” or “comprising”, will be understood to imply the inclusion of stated elements but not the exclusion of any other elements.

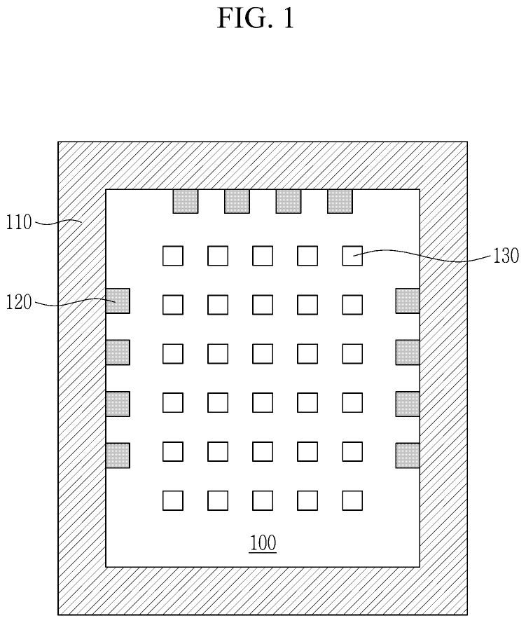

FIG. 1 is a schematic top plan view of a substrate for a semiconductor package according to embodiments of the present disclosure.

As shown in FIG. 1, a substrate for a semiconductor package includes a substrate main body 100 (also referred to as the substrate 100 herein), a plurality of bonding pads 120 and 130 disposed on a first surface of the substrate main body 100, and an underfill dam 110 surrounding the plurality of bonding pads 120 and 130.

The substrate main body 100 may be mainly made of an insulating material. Various materials may be used for the substrate main body 100, and the material is not limited in the present disclosure. In addition, in the present disclosure, a substrate for a semiconductor package includes a carrier of any shape or material on which a semiconductor die can be mounted on a surface thereof.

The plurality of bonding pads 120 and 130 are provided on the first surface of the substrate main body 100. The plurality of bonding pads may include bonding pads 130 for flip-chip bonding and bonding pads 120 for wire bonding.

The bonding pads 130 may be electrically connected with a bottom die through solder bumps. The bonding pads 120 may be electrically connected to a top die stacked on an upper surface of the bottom die through wires. When the bonding pads 120 are connected to the top die through a wire, they need to be disposed outside a region where the bottom die is mounted.

In some embodiments, as shown in FIG. 1, since most semiconductor dies have a quadrangle plane or shape, the bonding pads 120 may be disposed adjacent to the three sides of the bottom die. However, the bonding pads 120 may be disposed adjacent to one side of the bottom die, or may be disposed adjacent to two side sides of the bottom die.

In some embodiments, as shown in FIG. 1, the bonding pads 120 may not be disposed adjacent to only one side of the bottom die. An underfill solution may be provided from one of the sides where the bonding pads 120 are not disposed.

The underfill dam 110 closes a perimeter of a region where at least the bottom die is mounted to limit the diffusion of the underfill solution. The material or shape of the underfill dam 110 is not limited as long as it has a height sufficient to suppress the diffusion of the underfill solution. In some embodiments, the underfill dam 110 may be an insulation layer having a thickness of 10 μm or more. The insulation layer may be a solder resist (SR) coated on the first surface of the substrate main body 100.

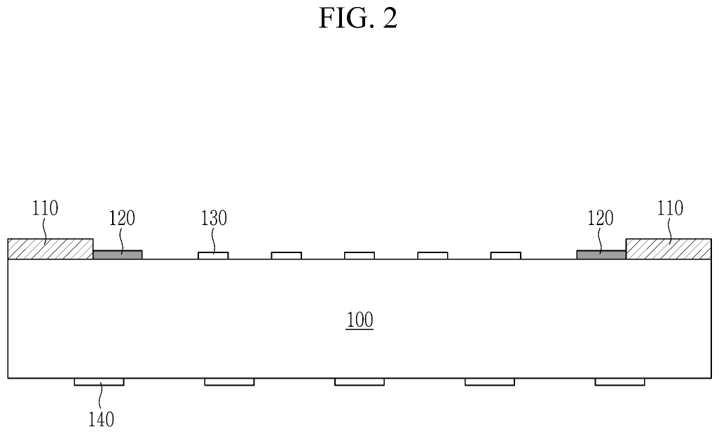

FIG. 2 is a schematic cross-sectional view of the substrate for the semiconductor package of FIG. 1.

Although it is not illustrated in FIG. 1, a plurality of metal pads 140 are provided on a second surface opposite to the first surface of the substrate main body 100. At least some of the plurality of metal pads 140 on the second surface may be electrically connected to at least some of the plurality of bonding pads 120, 130 on the first surface through conductive vias. Although not shown, an electrical circuit may be provided inside or on a surface of the substrate main body 100, and the plurality of bonding pads 120, 130 and the plurality of metal pads 140 may be electrically connected by the electric circuit according to a predetermined design.

The underfill dam 110 may be an insulation layer having a thickness of 10 μm or more. The insulation layer may be solder resist (SR) coated on the first surface of the substrate main body 100. The substrate for the semiconductor package according to the present embodiment may be manufactured by additionally coating a solder resist in a conventional manufacturing process. In an embodiment, the underfill dam 110 is at a higher vertical level than the bonding pads 120. As a result, the diffusion of the underfill solution is limited by the underfill dam 110 and the bonding pads 120 may be immersed in the underfill solution. However, the underfill dam 110 need not be excessively high. The diffusion of the underfill solution can be effectively limited by using the surface tension of the underfill solution even with the underfill dam 110 having a thickness of 10 μm.

Hereinafter, a semiconductor package according to embodiments of the present disclosure will be described.

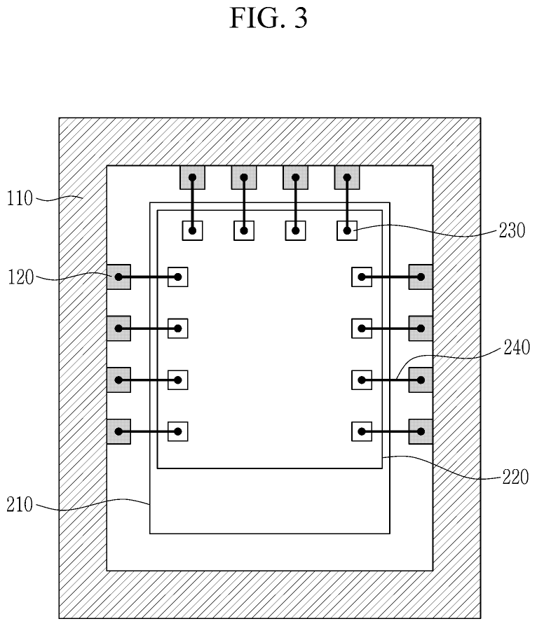

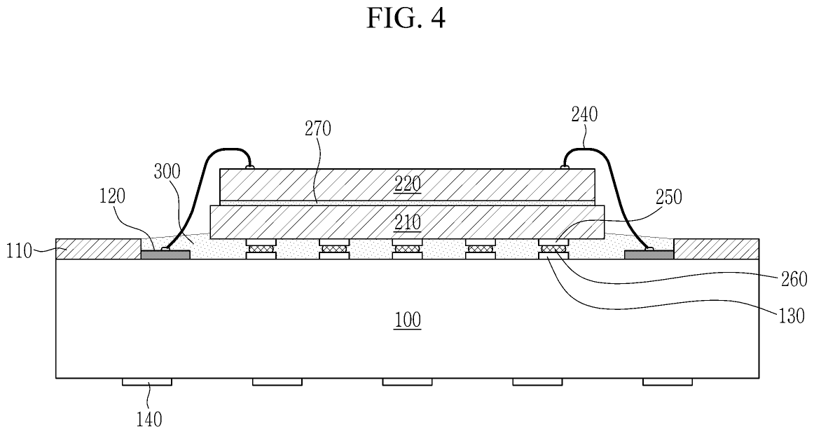

FIG. 3 is a schematic top plan view of a semiconductor package according to embodiments of the present disclosure, and FIG. 4 is a schematic cross-sectional view of the semiconductor package of FIG. 3.

A substrate main body 100, an underfill dam 110 and a plurality of bonding pads 120 and 130 provided on a first surface of the substrate main body 100, and a plurality of metal pads 140 provided on a second surface of the substrate main body 100 correspond to the constituent elements of the substrate shown in shown in FIG. 1 and FIG. 2, and therefore repeated descriptions thereof are omitted in the interest of brevity.

A bottom die 210 is mounted on the first surface of the substrate main body 100. A plurality of die pads 250 provided on one surface of the bottom die 210 may be electrically connected to the bonding pads 130 through a plurality of solder bumps 260.

A top die 220 is attached to an upper surface of the bottom die 210. Although not limited thereto, the top die 220 and the bottom die 210 may be attached by an adhesive tape 270. In another example, the top die 220 and the bottom die 210 may be attached by adhesive paste.

A plurality of die pads 230 provided on one surface of the top die 220 may be electrically connected to the bonding pads 120 by wires 240 for wire bonding.

A portion of the bonding pads 120 and the wires 240 bonded to the bonding pads 120 may be immersed in underfill 300. The bonding pads 120 may be covered by the underfill 300, and the wire bonding may be protected by the underfill 300. As a result, the problem of contaminating the bonding pads due to generation of underfill fume during a curing process of the underfill 300 does not fundamentally occur.

The underfill 300 fills or is in a space between the solder bumps 260 disposed between the bottom die 210 and the first surface of the substrate main body 100, which implements insulation between the solder bumps 260 and strengthens adherence between the bottom die 210 and the substrate.

As shown in FIG. 3, the bonding pads 120 are disposed adjacent to three sides of the bottom die 210. Correspondingly, die pads 230 are disposed along three sides on the upper surface of the top die 220. In some other embodiments, the bonding pads 120 may be disposed adjacent to one side, or may be disposed adjacent to two sides. Although not limited thereto, the bonding pads 120 may not disposed adjacent to only one side of the bottom die 210. An underfill solution may be provided from a region or side in which the bonding pads 120 are not disposed. In some other embodiments, the bonding pads 120 may be disposed adjacent to four sides of the bottom die 210. In this case, the underfill solution may be provided from any part of a region surrounded by the underfill dam 110. For example, an underfill solution may be provided from a corner portion.

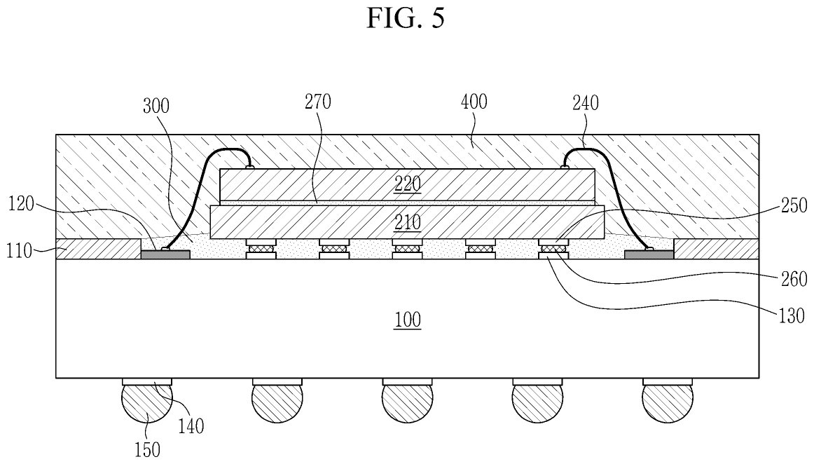

FIG. 5 is a schematic cross-sectional view of a semiconductor package according to other embodiments of the present disclosure.

The semiconductor package according to the present embodiment includes the semiconductor package shown in FIG. 3 and FIG. 4, and further includes a mold 400 at least partially covering a first surface side and a plurality of solder balls 150 provided on a plurality of metal pads 140 of a second surface.

The mold 400 seals an underfill dam 110, an underfill 300, wires 240, a bottom die 210, and a top die 220. An epoxy molding compound (EMC) may be used as a material for the mold 400.

The plurality of solder balls 150 enables the semiconductor package according to the present embodiment to be electrically connected to an external device through a reflow process. The external device may be, for example, a system board.

In some embodiments, the bottom die 210 may be a logic die and the top die 220 may be a memory die. In some embodiments, the bottom die 210 may be a modem die and the top die 220 may be a memory die. However, the present disclosure is not limited to these types of bottom die 210 and top die 220.

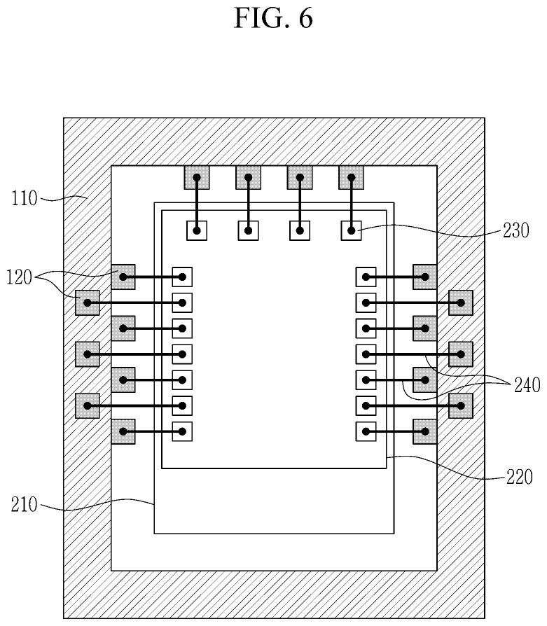

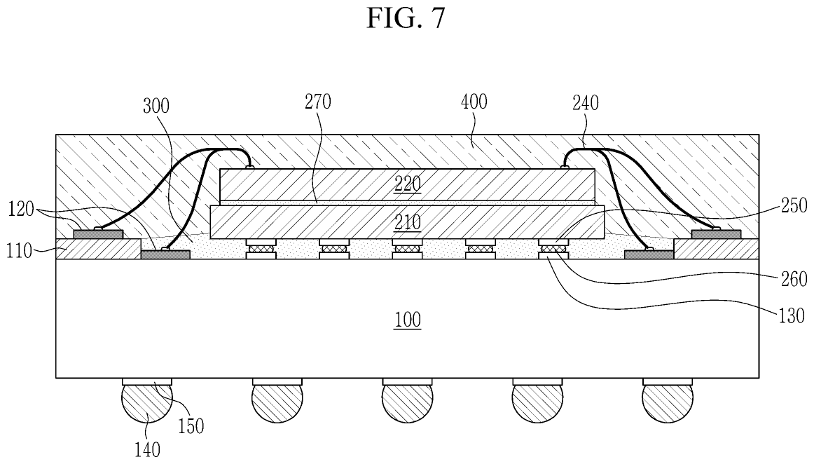

FIG. 6 is a schematic top plan view of a semiconductor package according to some embodiments of the present disclosure, and FIG. 7 is a cross-sectional view of the semiconductor package of FIG. 6.

A semiconductor package according to the present embodiment is substantially the same as the semiconductor package shown in FIG. 5, except that bonding pads 120 for wire bonding are provided on an underfill dam 110.

A part of the bonding pads 120 may be disposed in a region surrounded by the underfill dam 110, and another part of the bonding pads 120 may be disposed on a top surface of the underfill dam 110. The bonding pads 120 on the top surface of the underfill dam 110 are also electrically connected to die pads 230 provided on one surface (e.g., top or upper surface) of a top die 220 through wires 240.

The top die 220 manufactured by a wafer process may have die pads 230 having a higher density than the bonding pads 120 on the first surface of the substrate. Since bonding pads 120 are also provided on the underfill dam 110, more bonding pads 120 may be provided on the substrate.

Except that the bonding pads 120 are disposed on the surface of the underfill dam 110 and the bonding pads 120 are electrically connected to the die pads of the top die 220 by the wires 240, the description of the semiconductor package shown in FIG. 5 may be referred to for other constituent elements including the substrate main body 100, the bonding pads 130, the bottom die 210, the top die 220, the mold 400, the underfill 300, the plurality of solder balls 150, and therefore, repeated description is omitted here in the interest of brevity.

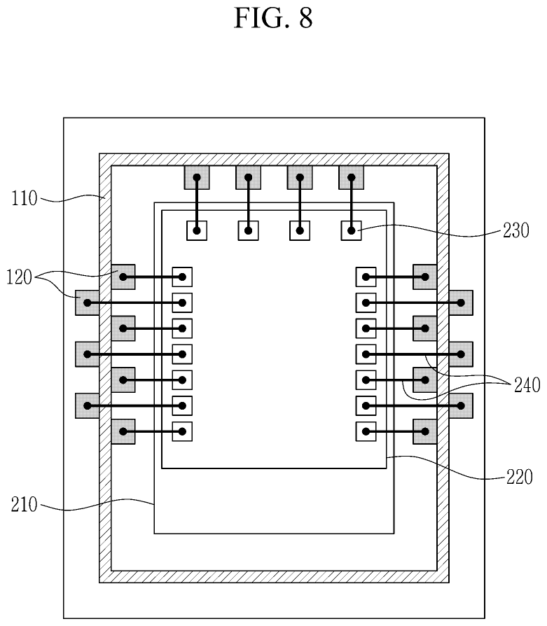

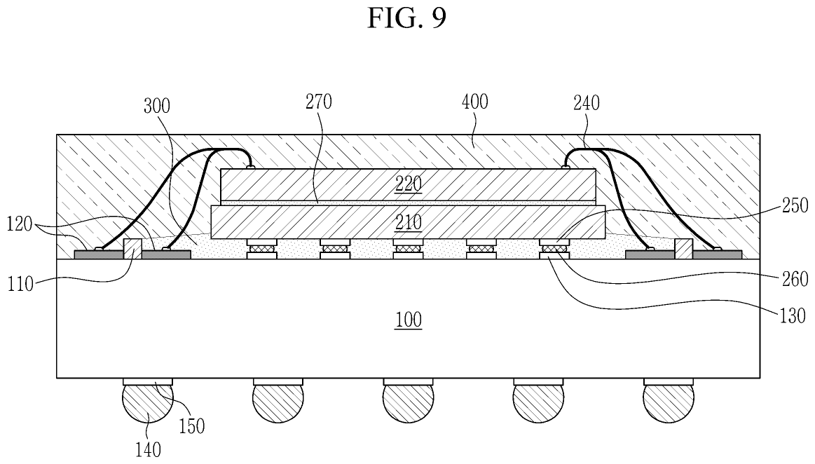

FIG. 8 is a schematic top plan view of a semiconductor package according to other embodiments of the present disclosure, and FIG. 9 is a schematic cross-sectional view of the semiconductor package of FIG. 8.

A semiconductor package according to the present embodiment is substantially the same as the semiconductor package of FIG. 5, except that bonding pads 120 for wire bonding are provided on an outer side of an underfill dam 110.

Some of the bonding pads 120 are disposed within a region surrounded by the underfill dam 110, and some of the bonding pads 120 are disposed outside the underfill dam 110. The bonding pads 120 disposed outside the underfill dam 110 are also electrically connected to die pads 230 provided on one surface of a top die 220 through wires 240.

The top die 220 manufactured by a wafer process may have die pads 230 having a higher density than the bonding pads 120 on a first surface of a substrate. Since the bonding pads 120 are also provided outside the underfill dam 110, more bonding pads 120 may be provided on the substrate.

Except that the bonding pads 120 are disposed on opposite sides of the underfill dam 110 and the bonding pads 120 are electrically connected to the die pads of the top die 220 by the wire 240, the description of the semiconductor package shown in FIG. 5 may be referred to for other constituent elements including the substrate main body 100, the bonding pads 130, the bottom die 210, the top die 220, the mold 400, the underfill 300, the plurality of solder balls 150, and therefore, repeated description is omitted here in the interest of brevity.

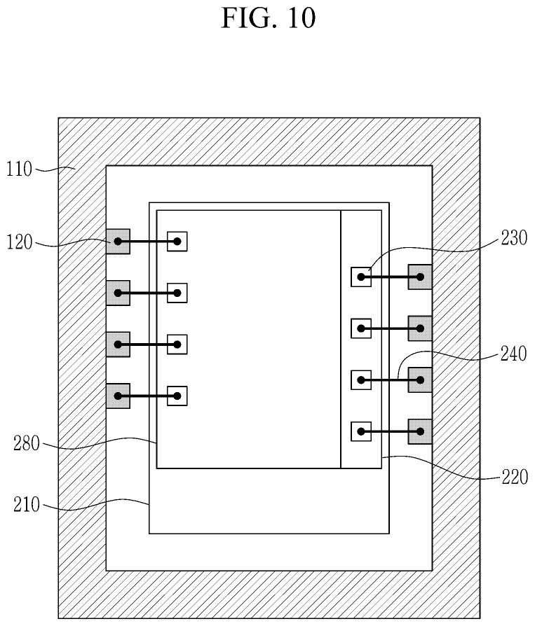

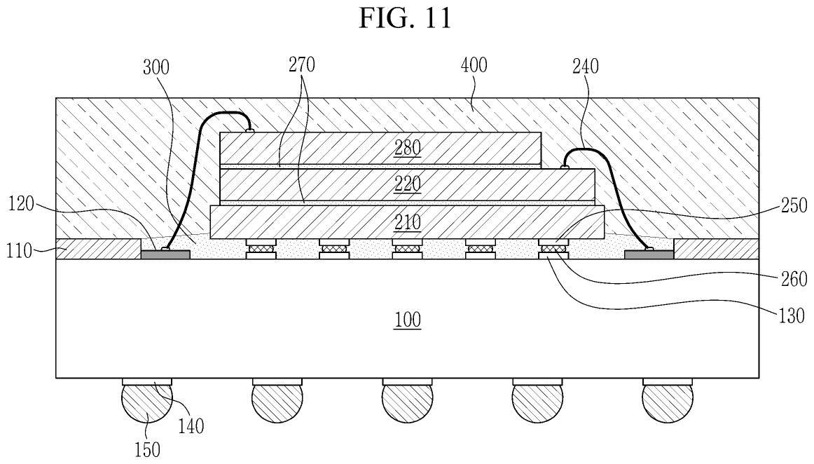

FIG. 10 is a schematic top plan view of a semiconductor package according to other embodiments of the present disclosure, and FIG. 11 is a schematic cross-sectional view of the semiconductor package of FIG. 10.

A semiconductor package according to the present embodiment includes an additional die 280 attached on an upper surface of a top die 220, a portion of bonding pads 120 are electrically connected to the top die 220 through wires 240, and another portion of the bonding pads 120 are electrically connected to the additional die 280 through the wires 240.

The additional die 280 may be attached to the upper surface of the top die 220 by, for example, an adhesive tape 270. Although the sizes of the additional die 280 and the top die 220 are not limited, the additional die 280 may be attached to at least a portion of the upper surface of the top die 220 to expose die pads 230 disposed on the upper surface of the top die 220.

In the present embodiment, the bonding pads 120 for wire bonding are disposed only in a region surrounded by an underfill dam 110, but for those skilled in the art, as shown in FIG. 6 and FIG. 8, it will be appreciated that the bonding pads 120 may additionally be disposed on the underfill dam 110, and/or outside the underfill dam 110. In this case, in an embodiment, the top die 220 is electrically connected to the bonding pads 120 disposed inside the underfill dam 110 by wires 240, and the additional die 280 is disposed on the underfill dam 110 and/or electrically connected to bonding pads 120 additionally disposed outside the underfill dam 110 by wires 240.

In addition, in the present embodiment, the top die 220 is connected to the bonding pads 120 disposed on one side by wires and the additional die 280 is connected to bonding pads 120 disposed on the opposite side by wires, but the top die 220 may be connected to the bonding pads 120 disposed on two sides by wires and the additional die 280 may be connected to bonding pads 120 disposed on one side by wires. Alternatively, the top die may be connected to the bonding pads 120 disposed on one side by wires and the additional die 280 may be connected to the bonding pads 120 disposed on two sides by wires.

Both the top die 220 and the additional die 280 may be memory dies, and the bottom die 210 may be a logic die/modem die.

For other constituent elements including the substrate main body 100, the bonding pads 130, the bottom die 210, the mold 400, the underfill 300, and the plurality of solder balls 150, the description of the semiconductor package shown in FIG. 5 may be referred to, and therefore the repeated description is omitted here in the interest of brevity.

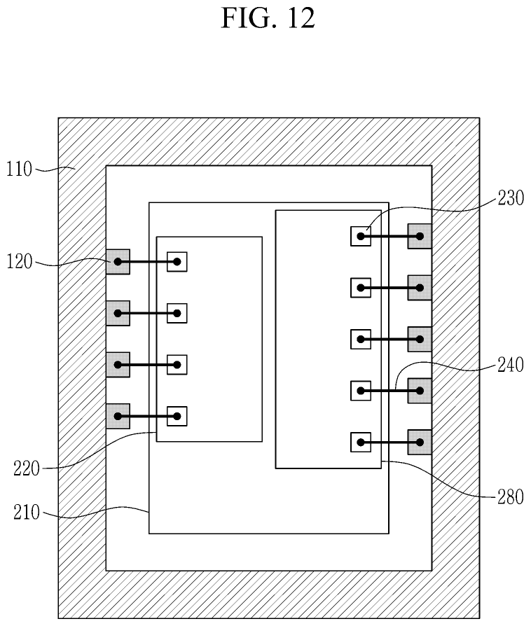

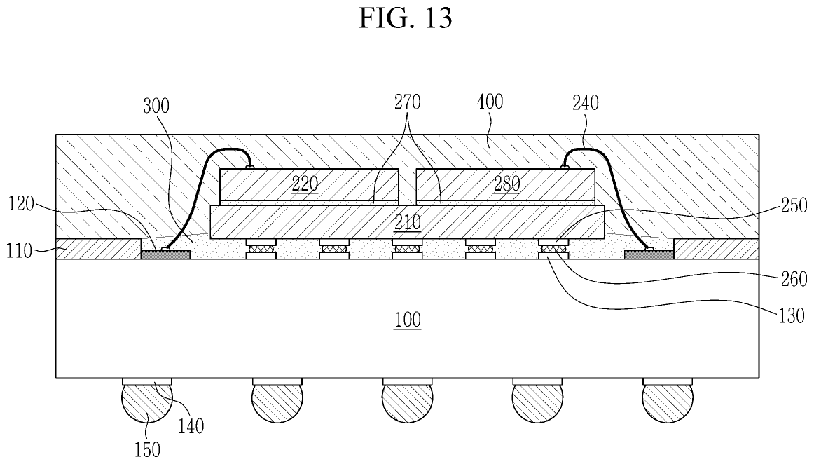

FIG. 12 is a schematic top plan view of a semiconductor package according to other embodiments of the present disclosure, and FIG. 13 is a schematic cross-sectional view of the semiconductor package of FIG. 12.

In a semiconductor package according to the present embodiment, a top die 220 and an additional die 280 are attached to an upper surface of a bottom die 210, a part of bonding pads 120 are electrically connected to the top die 220 through a wire 240, and another part of the bonding pads 120 are electrically connected to the additional die 280 through the wire 240.

The top die 220 and the additional die 280 may be attached to an upper surface of the bottom die 210 by, for example, an adhesive tape 270. The sizes or disposed positions of the top die 220 and the additional die 280 are not limited. Depending on the sizes and/or disposed positions of the top die 220 and additional die 280, the bonding pads 120 may be disposed.

In the present embodiment, the bonding pads 120 for wire bonding are disposed only in a region surrounded by an underfill dam 110, but for those skilled in the art, as shown in FIG. 6 and FIG. 8, it will be appreciated that the bonding pads 120 may additionally be disposed on the underfill dam 110, and/or outside the underfill dam 110. In this case, in an embodiment, the top die 220 is electrically connected to the bonding pads 120 disposed inside the underfill dam 110 by wires 240, and the additional die 280 is disposed on the underfill dam 110 and/or electrically connected to bonding pads 120 additionally disposed outside the underfill dam 110 by wires 240.

In addition, in the present embodiment, the top die 220 is connected to the bonding pads 120 disposed on one side by wires and the additional die 280 is connected to bonding pads 120 disposed on the opposite side by wires, but the top die 220 may be connected to the bonding pads 120 disposed on two sides by wires and the additional die 280 may be connected to bonding pads 120 disposed on one side by wires. Alternatively, the top die may be connected to the bonding pads 120 disposed on one side by wires and the additional die 280 may be connected to the bonding pads 120 disposed on two sides by wires.

Both the top die 220 and the additional die 280 may be memory dies, and the bottom die 210 may be a logic die/modem die.

For other constituent elements including the substrate main body 100, the bonding pads 130, the bottom die 210, the mold 400, the underfill 300, and the plurality of solder balls 150, the description of the semiconductor package shown in FIG. 5 may be referred to, and therefore the repeated description is omitted here in the interest of brevity.

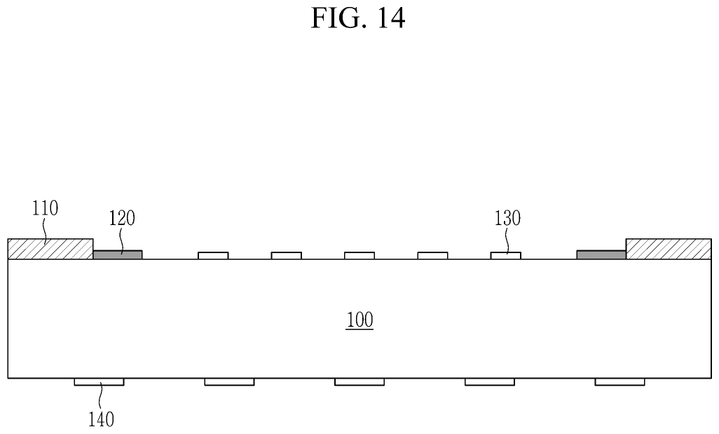

FIGS. 14 to 20 are provided for description of a manufacturing method of a semiconductor package according to embodiments of the present disclosure. In the present embodiment, a manufacturing method of the semiconductor package shown in FIG. 5 will be disclosed as an example.

In FIG. 14, on a first surface, a substrate including a plurality of bonding pads 120 and 130 and an underfill dam 110 surrounding the plurality of bonding pads 120 and 130 is prepared.

The plurality of bonding pads may include bonding pads 120 for wire bonding and bonding pads 130 for flip-chip bonding. The bonding pads 120 may be disposed around the bonding pads 130.

The underfill dam 110 may be provided along an edge of the substrate main body 100. The underfill dam 110 may be a solder resist (SR) coated on the first surface of the substrate main body 100.

The substrate according to the present embodiment is substantially the same as the substrate shown in FIG. 1 and FIG. 2, and therefore the description referred to as FIG. 1 and FIG. 2 may be applied.

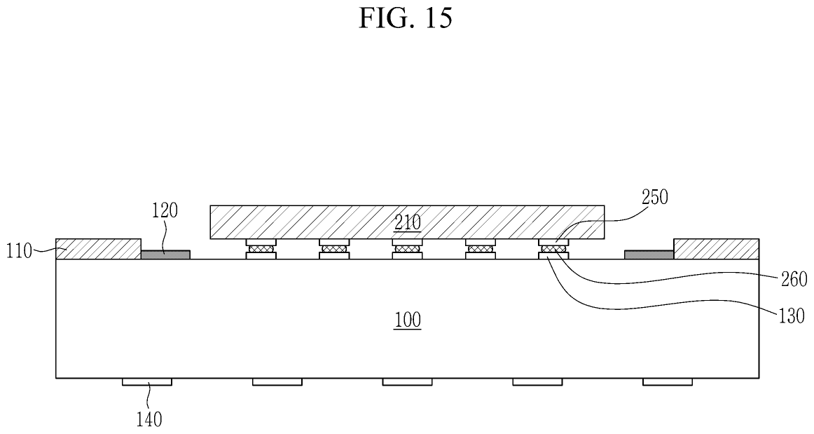

In FIG. 15, the bottom die 210 is mounted on the first surface of the substrate. A plurality of die pads 250 are provided on one surface of the bottom die 210, and the plurality of die pads 250 may be bonded to the bonding pads 130 through the solder bumps 260. Although the solder bumps 260 are used in the present embodiment, copper pillars, micro bumps, and the like may be used.

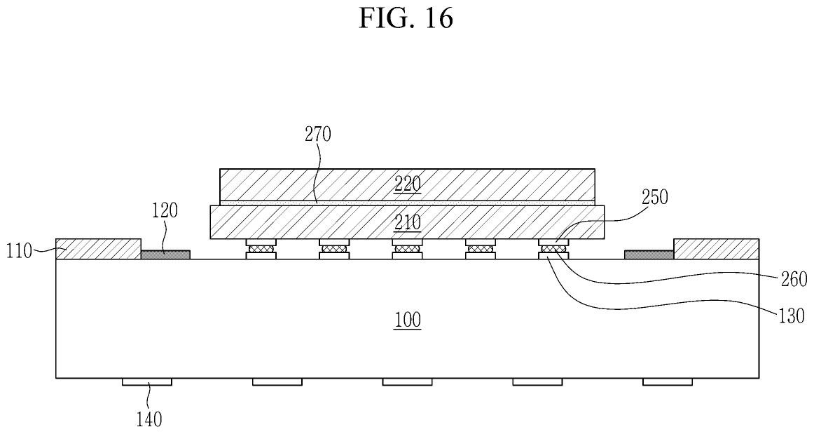

In FIG. 16, the top die 220 may be attached to the upper surface of the bottom die 210 through an adhesive tape 270. Adhesive paste may be used instead of the adhesive tape 270.

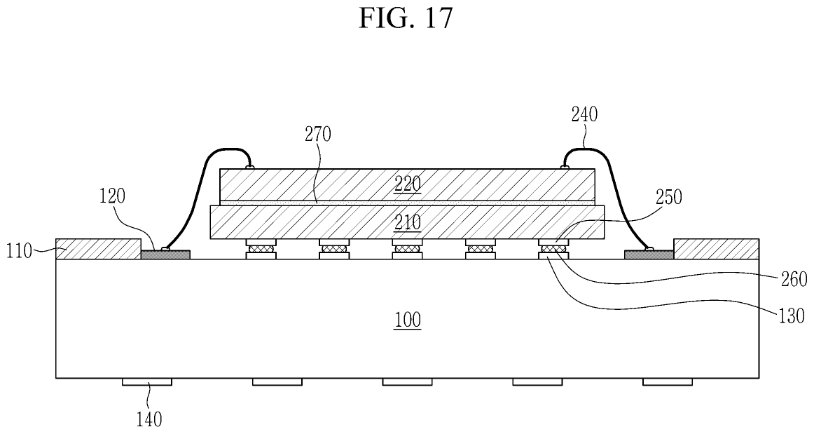

In FIG. 17, a plurality of die pads provided on the upper surface of the top die 220 are electrically connected to the bonding pads 120 by the wires 240. Since the wire bonding process is performed before the underfill process, there is no effect from underfill fume generated during a hardening process of the underfill solution.

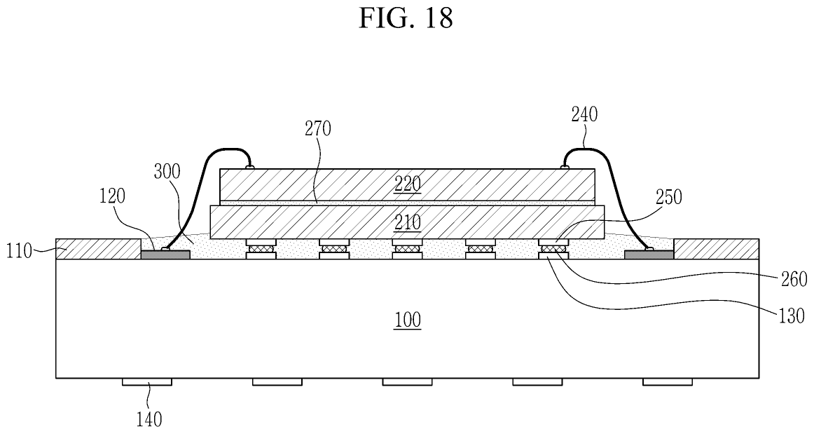

In FIG. 18, the underfill solution is implanted into a region surrounded by the underfill dam 110.

The underfill solution fills or is in a gap between the bottom die 210 and the first surface of the substrate and covers at least a portion of the bonding pads 120 and the wire 240 bonded to the bonding pads 120. After the underfill solution is cured, the underfill 300 achieves insulation between the solder bumps 260, firmly fixes the bottom die 210 to the substrate, and protects the bonding pads 120.

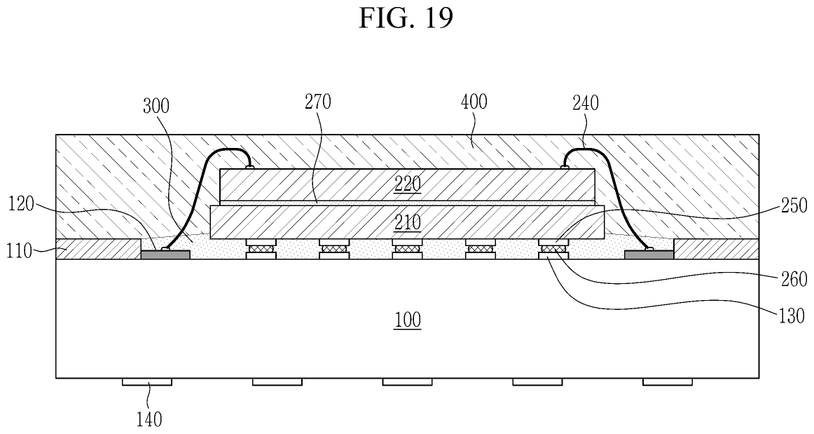

In FIG. 19, the mold 400 seals the constituent elements disposed on the first surface side of the substrate. This process is also called encapsulation.

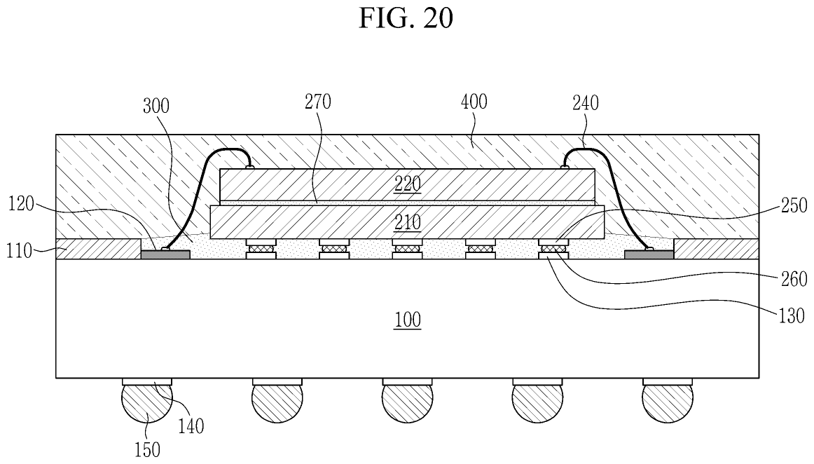

In FIG. 20, the plurality of solder balls 150 are disposed on a plurality of metal pads 140 provided on a second surface of the substrate main body 100 opposite to the first surface.

By the above process, the semiconductor package shown in FIG. 5 is manufactured. Since the underfill process is performed after wire bonding and the bonding pads for wire bonding are immersed in the underfill solution in the underfill process, there is no problem that the underfill fume affect the bonding pads and cause bonding defects.

For those skilled in the art, a method for manufacturing the semiconductor package shown in FIG. 6 to FIG. 13 can be readily derived from the manufacturing method described above, and therefore a detailed description of the method for manufacturing the semiconductor packages is omitted in the interest of brevity.

Although example embodiments have been described in detail above, the scope of the present disclosure is not limited thereto, and various modifications apparent to a person of an ordinary skill in the art using the inventive concepts of the present disclosure defined in the following claims also fall within the scope of the present disclosure.

What is claimed is:

1. A substrate for a semiconductor package, comprising:
a first surface configured to receive a semiconductor chip;
a second surface opposite the first surface;
a plurality of bonding pads on the first surface; and
an underfill dam surrounding the plurality of bonding pads and configured to limit diffusion of an underfill,
where the plurality of bonding pads include first bonding pads for flip-chip bonding and second bonding pads for wire bonding disposed around the first bonding pads.

2. The substrate for the semiconductor package of claim 1, wherein:
the underfill dam is an insulation layer with a thickness of 10 μm or more.

3. The substrate for the semiconductor package of claim 2, wherein:
the insulation layer is a solder resist (SR) coated on the first surface.

4. The substrate for the semiconductor package of claim 1, further comprising third bonding pads for wire bonding on the underfill dam.

5. The substrate for the semiconductor package of claim 1, further comprising third bonding pads for wire bonding outside the underfill dam on the first surface.

6. A semiconductor package comprising:
a substrate including a first surface and a second surface opposite the first surface;
a bottom die electrically connected to first bonding pads on the first surface of the substrate by solder bumps;
a top die that on the bottom die and electrically connected to second bonding pads on the first surface of the substrate by wires;
an underfill in a gap between the substrate and the bottom die;
an underfill dam surrounding the first bonding pads and the second bonding pads on the first surface of the substrate and is configured to restrict diffusion of the underfill;
a mold that at least partially covers elements on the first surface of the substrate; and
a plurality of solder balls on the second surface of the substrate,
wherein the second bonding pads and a part of each of the wires bonded to the second bonding pads are immersed in the underfill.

7. The semiconductor package of claim 6, wherein:
the underfill dam has a thickness of 10 μm or more and has a maximum height lower than a maximum height of the bottom die.

8. The semiconductor package of claim 7, wherein:
the underfill dam is a solder resist (SR) coated on the first surface of the substrate.

9. The semiconductor package of claim 6, wherein:
the second bonding pads extend along at least one side of the bottom die and do not extend along at least one other side of the bottom die.

10. The semiconductor package of claim 9, wherein:
the second bonding pads are adjacent three sides of the bottom die, and
a region for implantation of an underfill solution is provided on the remaining one side of the bottom die.

11. The semiconductor package of claim 6, further comprising third bonding pads for wire bonding on the underfill dam.

12. The semiconductor package of claim 11, wherein:
the third bonding pads are electrically connected to the top die by wires.

13. The semiconductor package of claim 11, further comprising an additional chip on the top die,
wherein the third bonding pads are electrically connected to the additional chip by wires.

14. The semiconductor package of claim 6, further comprising third bonding pads for wire bonding outside the underfill dam on the first surface of the substrate.

15. The semiconductor package of claim 14, wherein:
the third bonding pads are electrically connected to the top die by wires.

16. The semiconductor package of claim 14, further comprising an additional chip on the top die,
wherein the third bonding pads are electrically connected to the additional chip by wires.

17. The semiconductor package of claim 6, further comprising an additional chip on the top die,
wherein a portion of the second bonding pads are electrically connected to the top die, and another portion of the second bonding pads are electrically connected to the additional chip.

18. The semiconductor package of claim 6, wherein:
the top die comprises a plurality of top dies, and
each of the top dies is electrically connected to adjacent ones of the second bonding pads by wires.

19. A manufacturing method of a semiconductor package, comprising:
preparing a substrate including a plurality of bonding pads and an underfill dam surrounding the plurality of bonding pads on a first surface of the substrate;
mounting a bottom die on the first surface of the substrate, wherein the bottom die is electrically connected to first bonding pads among the plurality of bonding pads by flip-chip bonding;
attaching a top die to an upper surface of the bottom die;
electrically connecting the top die to second bonding pads among the plurality of bonding pads by wire bonding using wires;
providing an underfill solution into a region surrounded by the underfill dam until a gap between the bottom die and the first surface of the substrate is filled by the underfill solution and the second bonding pads and a part of each of the wires bonded to the second bonding pads are immersed in the underfill solution;
curing the underfill solution;
molding the first surface of the substrate; and
providing a plurality of solder bumps on a second surface of the substrate opposite the first surface of the substrate.

20. The manufacturing method of the semiconductor package of claim 19, wherein:
the preparing the substrate comprises preparing the underfill dam by coating a solder resist (SR) on a region surrounding the plurality of bonding pads on the first surface of the substrate.
